(19) United States
(12) Patent Application Publication
(10) Pub. No.: US 2022/0384186 A1
(43) Pub. Date: Dec. 1, 2022

(54) METHODS TO ENABLE SEAMLESS HIGH QUALITY GAPFILL

(71) Applicant: Lam Research Corporation, Fremont, CA (US)

(72) Inventors: Douglas Walter Agnew, Portland, OR (US); Joseph R. Abel, West Linn, OR (US); Eli Jeon, Sherwood, OR (US)

(73) Assignee: Lam Research Corporation, Fremont, CA (US)

(21) Appl. No.: 17/755,269

(22) PCT Filed: Oct. 29, 2020
(86) PCT No.: PCT/US2020/057991

§ 371 Date: Apr. 25, 2022

Related U.S. Application Data
(60) Provisional application No. 62/927,549, filed on Oct. 29, 2019.

(51) Int. Cl. H01L 21/02

(52) U.S. Cl. CPC H01L 21/02318; H01L 21/02164; H01L 21/02274; H01L 21/0228

(57) ABSTRACT

Methods and apparatuses for depositing material into high aspect ratio features are described herein. Methods involve depositing an oxide material using a hydrogen-containing oxidizing chemistry. Methods may also involve thermally treating deposited oxide material in the presence of hydrogen to remove seams within the deposited oxide material.

### INCORPORATED BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Many semiconductor device fabrication processes involve forming films including oxide films such as silicon oxide. Deposition of silicon oxide films may involve chemical vapor deposition (CVD) or atomic layer deposition (ALD), as well as plasma enhanced depositions, but in some cases it may be difficult to achieve a high quality film. This can be a particular challenge when depositing films in gaps.

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Disclosed herein are methods and systems of depositing a silicon oxide film. In one aspect of the embodiments herein, a method is presented, the method including: depositing an oxide gapfill material into patterned features of a layer of a substrate using a hydrogen-containing oxidizing chemistry, wherein the deposited oxide gapfill material has a plurality of seams within the patterned features; and thermally treating the deposited oxide gapfill material in the presence of hydrogen-containing compounds and/or oxygen-containing compounds to thereby reduce the extent of the seams.

In some embodiments, depositing the oxide gapfill material is performed by an atomic layer deposition (ALD) process. In some embodiments, the ALD process includes one or more cycles of: flowing oxide gapfill precursor, and flowing an oxidizing chemistry including H₂ and O₂. In some embodiments, the oxidizing chemistry additionally includes N₂O, CO₂, H₂O, or combinations thereof. In some embodiments, a ratio of volumetric flow rate between H₂ and O₂ when flowing the oxidizing chemistry is between about 1:10 and about 1:1. In some embodiments, the oxide gapfill precursor includes aminosi lanes, halosilanes, alkylsi lanes, silane, or combinations thereof. In some embodiments, depositing the oxide gapfill material is performed by a chemical vapor deposition process. In some embodiments, the oxide gapfill material is silicon oxide. In some embodiments, an aspect ratio of the patterned features is between about 5:1 and about 80:1.

In some embodiments, thermally treating the deposited oxide gapfill material is performed at a temperature of at least about 400° C. In some embodiments, thermally treating the deposited oxide gapfill material is performed at a temperature between about 400° C. and about 850° C. In some embodiments, thermally treating the deposited oxide gapfill material is performed under conditions that form H₂O. In some embodiments, thermally treating the deposited oxide gapfill material is performed in the presence of H₂ and O₂. In some embodiments, a volumetric ratio of H₂ to O₂ during thermally treating the deposited oxide gapfill material is between about 10:1 and about 1:1. In some embodiments, the oxygen-containing compounds include N₂O, CO₂, H₂O, or combinations thereof. In some embodiments, the hydrogen-containing compounds include protic acids. In some embodiments, a hydrogen % within the deposited oxide gapfill material prior to thermally treating the deposited oxide gapfill material is at least about 0.1%. In some embodiments, the layer includes polySi-SiO₂, W—SiO₂, SiN—SiO₂, SiNO—SiO₂, SiCO—SiO₂, SiC—SiO₂, Ta—SiO₂, Ta, Hf, Zr, Ge, GeO₂, or combinations thereof.

In another aspect of the embodiments herein, a method is presented, the method including: receiving a substrate having patterned features within a first layer; depositing a oxide gapfill material into the patterned features; and thermally treating the deposited oxide gapfill material in the presence of hydrogen-containing compounds and/or oxygen-containing compounds. In some embodiments, depositing the oxide gapfill material is performed by an atomic layer deposition OLD) process. In some embodiments, the ALD process includes one or more cycles of: flowing oxide gapfill precursor, and flowing an oxidizing chemistry including H₂ and O₂. In some embodiments, the oxidizing chemistry additionally includes N₂O, CO₂, H₂O, or combinations thereof, in some embodiments, a ratio of volumetric flow rate between H₂ and O₂ when flowing the oxidizing chemistry is between about 1:10 and about 1:1. In some embodiments, the oxide gapfill precursor includes aminosilanes, halosilanes, alkylsilanes, silane, or combinations thereof. In some embodiments, depositing the oxide gapfill material is performed by a chemical vapor deposition process. In some embodiments, the oxide gapfill material is silicon oxide. In some embodiments, an aspect ratio of the patterned features is between about 5:1 and about 80:1. In some embodiments, thermally treating the deposited oxide gapfill material is performed at a temperature of at least about 400° C. In some embodiments, thermally treating the deposited oxide gapfill material is performed at a temperature between about 400° C. and about 850° C.

In some embodiments, thermally treating the deposited oxide gapfill material is performed under conditions that form H₂O. In some embodiments, thermally treating the deposited oxide gapfill material is performed in the presence of H₂ and O₂. In some embodiments, a volumetric ratio of H₂ to O₂ during thermally treating the deposited oxide gapfill material is between about 10:1 and about 1:1. In some embodiments, the oxygen-containing compounds include N₂O, CO₂, H₂O, or combinations thereof. In some embodiments, the hydrogen-containing compounds include protic acids. In some embodiments, a hydrogen % within the deposited oxide gapfill material prior to thermally treating the deposited oxide gapfill material is at least about 0.1%. In some embodiments, the layer includes polySi-SiO₂, W—SiO₂, SiN—SiO₂, SiNO—SiO₂, SiCO—SiO₂, SiC—SiO₂, Ta—SiO₂, Ta, Hf, Zr, Ge, GeO₂, or combinations thereof.

In another aspect of the embodiments herein, a method is presented, the method including: prior to thermally treating a substrate, depositing an oxide gapfill material into patterned features of the substrate by an atomic layer deposition (ALD) process, wherein the ALD process includes one or more cycles of: flowing gapfill precursor, and flowing an oxidizing chemistry including H₂ and O₂. In some embodiments, depositing the oxide gapfill material is performed by an atomic layer deposition (ALD) process. In some embodiments, the ALD process includes one or more cycles of: flowing oxide gapfill precursor, and flowing an oxidizing chemistry including H₂ and O₂. In some embodiments, the oxidizing chemistry additionally includes N₂O, CO₂, H₂O, or combinations thereof. In some embodiments, a ratio of volumetric flow rate between H₂ and O₂ when flowing the oxidizing chemistry is between about 1:10 and about 1:1. In some embodiments, the oxide gapfill precursor includes aminosilanes, halosilanes, alkylsilanes, silane, or combinations thereof. In some embodiments, depositing the oxide gapfill material is performed by a chemical vapor deposition process. In some embodiments, the oxide gapfill material is silicon oxide. In some embodiments, an aspect ratio of the patterned features is between about 5:1 and about 80:1.

In some embodiments, the method further comprises thermally treating the deposited oxide gapfill material. In some embodiments, thermally treating the deposited oxide gapfill material is performed at a temperature of at least about 400° C. In some embodiments, thermally treating the deposited oxide gapfill material is performed at a temperature between about 400° C. and about 850° C. In some embodiments, thermally treating the deposited oxide gapfill material is performed under conditions that form H₂O. In some embodiments, thermally treating the deposited oxide gapfill material is performed in the presence of H₂ and O₂. In some embodiments, a volumetric ratio of H₂ to O₂ during thermally treating the deposited oxide gapfill material is between about 10:1 and about 1:1. In some embodiments, the oxygen-containing compounds include N₂O, CO₂, H₂O, or combinations thereof. In some embodiments, the hydrogen-containing compounds include protic acids. In some embodiments, a hydrogen % within the deposited oxide gapfill material prior to thermally treating the deposited oxide gapfill material is at least about 0.1%. In some embodiments, the layer includes polySi-SiO₂, W—SiO₂, SiN—SiO₂, SiNO—SiO₂, SiCO—SiO₂, SiC—SiO₂, Ta—SiO₂, Ta, Hf Zr, Ge, GeO₂, Al₂O₃, TiO₂, NiO, CoO, Co₂O, MoO₃, HfO, TaO or combinations thereof.

In another aspect of the embodiments herein, a method is presented, the method including: receiving a substrate having a patterned first layer filled with oxide gapfill material having seams within the oxide gapfill material; and thermally treating the oxide gapfill material in the presence of hydrogen-containing compounds and/or oxygen-containing compounds to thereby reduce the extent of the seams. In some embodiments, the oxide gapfill material is deposited using a hydrogen-containing oxide chemistry. In some embodiments, depositing the oxide gapfill material is performed by an atomic layer deposition (ALM process. In some embodiments, the ALD process includes one or more cycles of: flowing oxide gapfill precursor, and flowing an oxidizing chemistry including H₂ and O₂. In some embodiments, the oxidizing chemistry additionally includes N₂O, CO₂, H₂O, or combinations thereof. In some embodiments, a ratio of volumetric flow rate between H₂ and O₂ when flowing the oxidizing chemistry is between about 1:10 and about 1:1. In some embodiments, the oxide gapfill precursor includes aminosilanes, halosilanes, alkylsilanes, silane, or combinations thereof. In some embodiments, depositing the oxide gapfill material is performed by a chemical vapor deposition process. in some embodiments, the oxide gapfill material is silicon oxide. in some embodiments, an aspect ratio of the patterned features is between about 5:1 and about 80:1.

In some embodiments, thermally treating the deposited oxide gapfill material is performed at a temperature of at least about 400° C. In some embodiments, thermally treating the deposited oxide gapfill material is performed at a temperature between about 400° C. and about 850° C. In some embodiments, thermally treating the deposited oxide gapfill material is performed under conditions that form H₂O. In some embodiments, thermally treating the deposited oxide gapfill material is performed in the presence of H₂ and O₂. In some embodiments, a volumetric ratio of H₂ to O₂ during thermally treating the deposited oxide gapfill material is between about 10:1. and about 1:1. In some embodiments, the oxygen-containing compounds include N₂O, CO₂, H₂O, or combinations thereof. In some embodiments, the hydrogen-containing compounds include protic acids. In some embodiments, a hydrogen % within the deposited oxide gapfill material prior to thermally treating the deposited oxide gapfill material is at least about 0.1%. In some embodiments, the layer includes polySi-SiO₂, W—SiO₂, SiN—SiO₂, SiNO—SiO₂, SiCO—SiO₂, SiC—SiO₂, Ta—SiO₂, Ta, Hf, Zr, Ge, GeO₂, or combinations thereof.

These and other features of the disclosed embodiments will be described in detail below with reference to the associated drawings.

### is BRIEF DESCRIPTION OF DRAWINGS

FIG. 1 presents an illustration of seams that may form during a deposition process.

FIG. 2 presents a flowchart for an example embodiment.

FIG. 3 presents another flowchart for an atomic layer deposition (ALD) process of an example embodiment.

FIG. 4 presents a block diagram of a manifold that may be used during a deposition process as described herein.

FIGS. 5 and 6 are schematic diagrams of examples of process chambers for performing methods in accordance with disclosed embodiments.

### DETAILED DESCRIPTION

Semiconductor fabrication processes often include dielectric gap fill using chemical vapor deposition (CVD) and/or atomic layer deposition (ALD) methods to fill features. Described herein are methods of filling features with dielectric material including but not limited to silicon oxide, and related systems and apparatuses. The methods described herein can be used to fill vertically-oriented features formed in a substrate. Such features may be referred to as gaps, recessed features, negative features, unfilled features, or simply features. Filling such features may be referred to as gapfill. Features formed in a substrate can be characterized by one or more of narrow and/or re-entrant openings, constrictions within the feature, and high aspect ratios. In some implementations, a feature may have an aspect ratio of at least about 2:1, at least about 4:1, at least about 6:1, at least about 20:1, at least about 100:1, or greater. The substrate may be a silicon wafer, e.g., a 200-mm wafer, a 300-mm wafer, or a 450-mm wafer, including wafers having one or more layers of material such as dielectric, conducting, or semi-conducting material deposited thereon.

A gapfill deposition process for oxide films may create seams in the deposited film. As the film conformally grows within a feature, a seam may form at the juncture between the films as they grow towards each from the sidewalls of the feature. Seams may be less dense areas of the oxide film and contribute to worse film qualities. Seams are generally undesirable due to increasing the chance of failure of a resulting semiconductor device.

Two techniques are described herein to address seams include depositing an oxide gapfill material using a hydrogen-containing oxidizing chemistry and thermally treating, or annealing, the oxide film in a hydrogen- and oxygen-containing environment. In some embodiments, both techniques may be used, while in other embodiments only one technique may be used. Oxide gapfill material, oxide film, and oxide material may be used interchangeably herein.

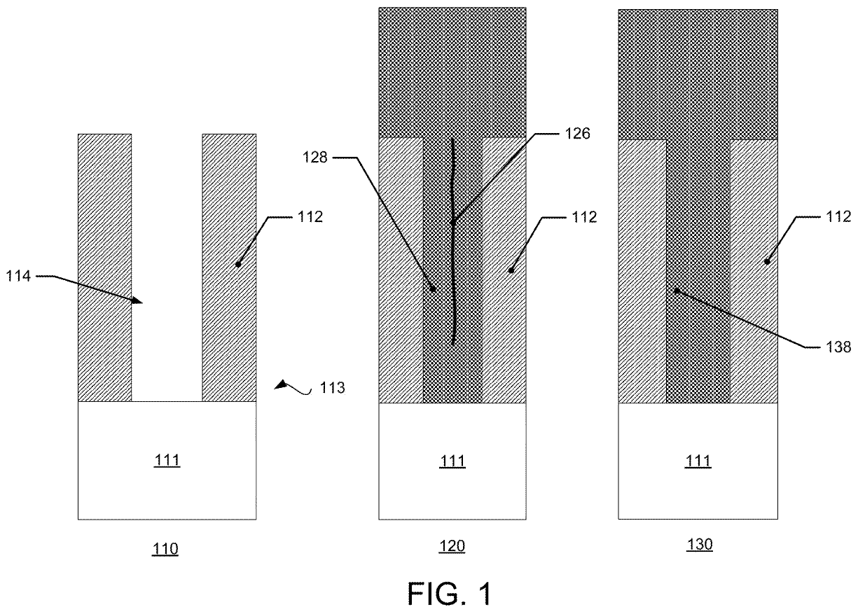

FIG. 1 provides an illustration of how seams may be formed and removed. In operation 110, substrate 113 has an underlying layer 111, a patterned layer 112, and features 114 within patterned layer 112. In operation 120, an oxide material 128 is deposited on substrate 113. As can be seen, a seam 126 may form within feature 114. It should be understood that while oxide material 128 is shown as depositing above patterned layer 112, in some embodiments there is no deposition on top of patterned layer 112, and oxide material 128 is only deposited within features 114. Additionally, while seam 126 is shown within feature 114, in some embodiments seam 126 may extend above the top of patterned layer 112. Furthermore, in some embodiments underlying layer 111 and patterned layer 112 may be different materials or the same material. In some embodiments, patterned layer 112 may include a multi-laminate stack having two or more materials, such a ONON (oxide-nitride-oxide-nitride) stack, a OPOP (silicon oxide on polysilicon) stack, or OMOM stack (silicon oxide on metal such as tungsten, cobalt, or molybdenum) and features 114 may be formed in such multi-layer substrates where sidewalls of the features include two or more compositions. In some embodiments, patterned layer 112 may include one or more of polySi-SiO₂, W—SiO₂, SiN—SiO₂, SiNO—SiO₂, SiCO—SiO₂, SiC—SiO₂, Ta—SiO₂, Ta, Hf, Zr, Ge, or GeO₂. In some embodiments the patterned layer 112 may be other metal layers.

In operation 130 substrate 113 has been thermally treated to reduce and in some embodiments substantially or completely remove seam 126. In some embodiments, after thermal treatment, oxide material 138 has no seams. In other embodiments, thermal treatment reduces the extent of seams but does not completely remove them. While seam 126 is shown as removed in operation 130, it should be understood that in some embodiments seam 126 has 1.0 been reduced in size, but is still present to a lesser degree.

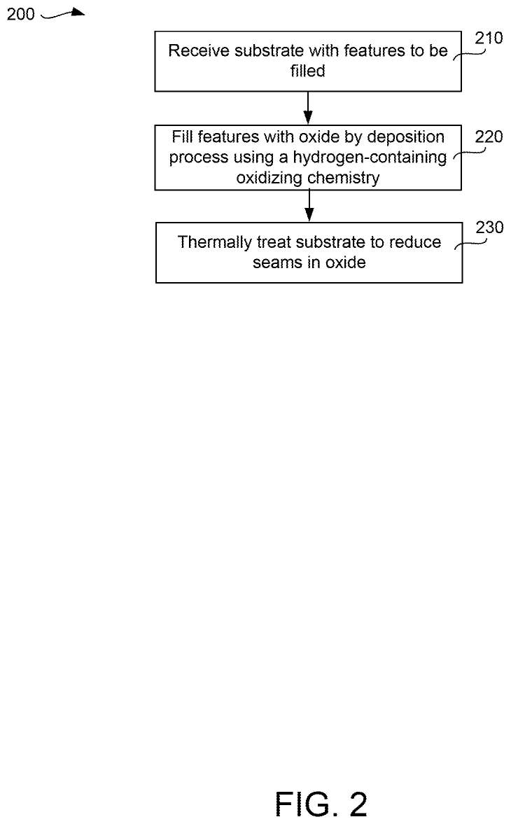

FIG. 2 presents a process flow diagram 200 for embodiments described herein. In operation 210, a substrate having features to be filled is received in a process chamber. In some embodiments, the substrate may be remaining in the process chamber from a prior operation, while in other embodiments the substrate may be provided to the process chamber. The substrate has patterned features to be filled, in some embodiments, patterned features may have an aspect ratio between width and depth of between about 5:1 and about 100:1.

In operation 220 the patterned features are filled with an oxide material by a deposition process using a hydrogen-containing oxidizing chemistry. In various embodiments, the dielectric material is silicon oxide. Silicon oxide may be deposited by ALD, plasma-enhanced ALD (PEALD), CVD, or plasma-enhanced CVD (PECVD). ALD is a technique that deposits thin layers of material using sequential self-limiting reactions. ALD processes use surface-mediated deposition reactions to deposit films on a layer-by-layer basis in cycles. As an example, an ALD cycle may include the following operations: (i) delivery/adsorption of a precursor, (ii) purging of the precursor from the chamber, (iii) delivery of a second reactant and optional plasma ignition, and (iv) purging of byproducts from the chamber. The reaction between the second reactant and the adsorbed precursor to form a film on the surface of a substrate affects the film composition and properties, such as nonuniformity, stress, wet etch rate, dry etch rate, electrical properties (e.g., breakdown voltage and leakage current), etc.

In one example of an ALD process, a substrate surface that includes a population of surface active sites is exposed to a gas phase distribution of a first precursor, such as a silicon-containing precursor, in a dose provided to a chamber housing the substrate. Molecules of this first precursor are adsorbed onto the substrate surface, including chemisorbed species and/or physisorbed molecules of the first precursor. It should be understood that when a compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of first precursor remaining in gas phase so that mostly or only the adsorbed species remain. In some implementations, the chamber may not be fully evacuated. For example, the reactor may be evacuated such that the partial pressure of the first precursor in gas phase is sufficiently low to mitigate a reaction. A second reactant, such as a hydrogen- and oxygen-containing gas, is introduced to the chamber so that some of these molecules react with the first precursor adsorbed on the surface. In some processes, the second reactant reacts immediately with the adsorbed first precursor. In other embodiments, the second reactant reacts only after a source of activation such as plasma is applied temporally. The chamber may then be evacuated again to remove unbound second reactant molecules. As described above, in some embodiments the chamber may not be completely evacuated. Additional ALD cycles may be used to build film thickness.

In some implementations, the ALL) methods include plasma activation. As described herein, the ALD methods and apparatuses described herein may be conformal film deposition (CFD) methods, which are described generally in U.S. patent application Ser. No. 13/084,399 (now U.S. Pat. No. 8,728,956), filed Apr. 11, 2011, and titled “PLASMA ACTIVATED CONFORMAL FILM DEPOSITION,” which is herein incorporated by reference in its entirety.

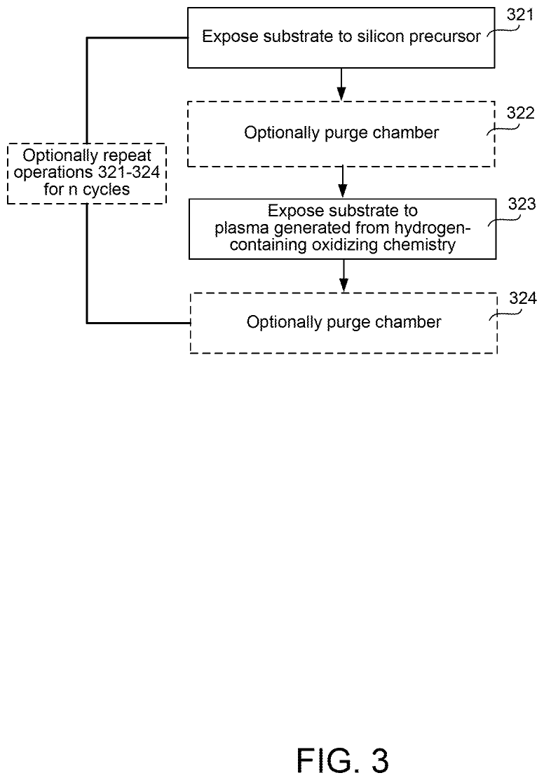

FIG. 3 presents a process flow diagram for a single ALD cycle. In operations 321, the substrate is exposed to a silicon-containing precursor, such as any of those described herein, to adsorb the precursor onto the surface of the feature. In various embodiments, this operation is self-limiting. In some embodiments, the precursor adsorbs to less than all of the active sites on the surface of the feature. In operation 322, the process chamber is optionally purged to remove any unadsorbed silicon-containing precursors. In operation 323, the substrate is exposed to an hydrogen-containing oxidizing chemistry and a plasma is ignited to form a first silicon oxide layer in the feature. In various embodiments, operation 323 converts the adsorbed silicon-containing precursor layer to silicon oxide. In operation 324, the process chamber is optionally purged to remove byproducts from the reaction between the silicon-containing precursor and the oxidant. Operations 321 through 324 may be optionally repeated for two or more cycles as desired to deposit silicon oxide to a desired thickness in the feature.

it should be noted that the processes described herein are not limited to a particular reaction mechanism. Thus, the process described with respect to FIG. 3 include all oxide deposition processes that use sequential exposures to a silicon-containing reactants and oxidizing plasmas, including those that are not strictly self-limiting. The process includes sequences in which one or more gases used to generate a plasma is continuously flowed throughout the process with intermittent plasma ignitions. Further, in some embodiments, thermal ALD using the described chemistries may be employed.

For depositing silicon oxide, one or more silicon-containing precursors may be used. Silicon-containing precursors suitable for use in accordance with disclosed embodiments include polysilanes (H₃Si—(SiH₂)ₙ—SiH₃), where n≥0. Examples of silanes are silane disilane (Si₂H₆), and organosilanes such as methylsilane, ethylsilane, isopropylsilane, t-butylsilane, dimethylsilane, diethylsilane, di-t-butylsilane, allylsilane, sec-butylsilane, hexylsilane, isoamylsilane, t-butyldisilane, di-t-butyldisilane, and the like.

A halosilane includes at least one halogen group and may or may not include hydrogens and/or carbon groups. Examples of halosilanes are iodosilanes, bromosilanes, chlorosilanes, and fluorosilanes. Although halosilanes, particularly fluorosilanes, may form reactive halide species that can etch silicon materials when a plasma is struck, a halosilane may not be introduced to the chamber when a plasma is struck in some embodiments, so formation of a reactive halide species from a halosilane may be mitigated. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like.

An aminosilane includes at least one nitrogen atom bonded to a silicon atom, but may also contain hydrogens, oxygens, halogens, and carbons. Examples of aminosilanes are mono-, di-, tri- and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, Cert-butylsilanamine, bis(tert-butylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃ and the like. A further example of an aminosilane is trisilylamine (N(SiH₃)).

Example oxidizing chemistries include one or more of oxygen gas, water, carbon dioxide, nitrous oxide, and combinations thereof. Hydrogen may be included in the oxidizing compound (e.g., water) or as a separate gas. In various embodiments, the substrate is exposed to the hydrogen-containing oxidizing chemistry and an inert gas simultaneously while the plasma is ignited. For example, in one embodiment, a mixture of hydrogen, oxygen and argon is introduced to the substrate while the plasma is ignited. Example inert gases include helium and argon. In some embodiments, the inert gas acts as a carrier gas to deliver the process gases to the substrate and is diverted upstream of the chamber. For deposition by ALD or PEALD, the silicon-containing precursor and the reactant are introduced sequentially in pulses, which may be separated by purging operations.

In some embodiments, hydrogen may be included in the oxidizing chemistry as diatomic hydrogen (H₂) or as part of the oxidizing compound (e.g., water), in some embodiments, compounds that readily donate a proton may be used, for example protic acids such as alcohols and/or carboxylic acids. While hydrogen or diatomic hydrogen is generally is used throughout the specification, it should be understood that other compounds that readily donate a proton, e.g., protic acids such as alcohols and/or carboxylic acids, may be used in addition to or instead of diatomic hydrogen.

In embodiments where a combination of any of ALD, PEALD, CND, and PECVD are used to deposit the dielectric material in operation 220, the same reactants and precursors may be used during both techniques. In some embodiments, different precursors may be selected depending on the technique. For example, in some embodiments, ALD may be performed using a halosilane, followed by PECVD using silane as the silicon-containing precursor. In some embodiments, a plasma is ignited during one or more of the techniques used to deposit the dielectric material.

Returning to FIG. 2, a hydrogen-containing oxide chemistry is used to deposit an oxide gapfill material into the features, such as a silicon oxide, in an operation 220. A hydrogen-containing oxide chemistry may include hydrogen and oxygen, and potentially an inert gas. In some embodiments the oxide chemistry may also include nitrous oxide, carbon dioxide, or water. Other oxidants such as carbon monoxide, nitric oxide, nitrogen dioxide, sulfur oxide, sulfur dioxide, and oxygen containing hydrocarbons may be used in addition to or instead of nitrous oxide, carbon dioxide, and water. Including hydrogen in the oxidation chemistry may provide two benefits. First, the hydrogen may react with any leftover reactants or byproducts from the oxidation of the silicon-containing precursor and increase the rate of removal/decrease the incorporation of byproducts into the film. For example, diethylamine may remain near the surface of the film after oxidation of MEAS. The depositing film is acidic, while the amine is basic. The hydrogen in the oxidation chemistry may react with the amine, reducing it and thus allowing it to be more easily removed.

A second benefit of adding hydrogen to the oxidization chemistry may be increasing the efficacy of a subsequent thermal treatment to remove seams in the deposited oxide film. Adding hydrogen to the oxidation chemistry may increase the hydrogen content of the film, potentially in the form of water or hydroxyl terminated silane species, the latter of which may contribute to the formation of seams. By increasing the water and/or H content of the film, a subsequent thermal treatment will be improved. Heating water within the film may cause water and/or H to react with terminated silane species that are not covalently linked with oxygen, reducing the seams. In some embodiments, extra hydrogen may react with silane species at the seam to cause a chemical reaction that causes covalent Si—O bonds to form that reduce seam size.

The ratio of hydrogen to oxygen in the oxidization chemistry gas flow may be between about 1:10 to about 1:1 H₂:O₂. In some embodiments gas flows may be about 5 slm H₂, about 5 slm O₂, and about 5 slm N₂O. Too much hydrogen may cause exothermic, explosive reactions. In some embodiments the hydrogen % in the deposited oxide gapfill material before operation 230 is at least about 0.1% or at least about 2%.

As noted above, the oxide deposition may also be performed by a CVD process. In such embodiments, hydrogen may be included in the silicon oxide deposition process to increase the hydrogen content in the film. Oxide deposition for the ALD or CVD process may be performed at about 550° C., or between about 400° C. and about 650° C. Chamber pressure may be between about 3 Torr to about 12 Torr. RE power during deposition could be between about 0.5-6 kW, and may include both high frequency (13.56 MHz) and low frequency (480 kHz) RE components.

In operation 230 the substrate is thermally treated to reduce the presence of seams within the oxide film or remove the seams. Thermal treatments may be performed in the same process chamber where the oxide deposition occurs or in a separate chamber. Thermal treatment may also be called an anneal. The thermal treatment involves heating the substrate to an annealing temperature, and exposing the substrate to oxygen and hydrogen. In various embodiments the anneal temperature is at least about 200° C., about 400° C., about 500° C., about 550° C., or about 600° C., at most about 850° C. or about 650° C., or between about 200° C. and about 650° C., between about 400° C. and about 850° C., or between about 550° C. and about 850° C. In some embodiments, diatomic hydrogen and oxygen are used, while in other embodiments hydrogen-containing compounds and/or oxygen-containing compounds may be used. In some embodiments, the hydrogen-containing compounds may include protic acids, e.g., alcohols or carboxylic acids. In sonic embodiments, the oxygen-containing compounds may include N₂O, O₂, CO₂, and/or O₃. In some embodiments, water may be used as both a hydrogen- and oxygen-containing compound.

Notably, one advantage of the present disclosure is that seams may be removed at a lower temperature by using a combination of hydrogen-containing oxidation chemistry during deposition and thermally treating the substrate in the presence of hydrogen and oxygen. Without the use of hydrogen and oxygen during the thermal treatment, the seams may be removed by heating the substrate to about 850° C. Thermal treatment at 600° C. without the use is of hydrogen and oxygen, including a plasma anneal using Ar and an inert gas anneal, did not remove seams to the same extent as the use of hydrogen and oxygen. An oxyhydrogen anneal provided better results than a plasma anneal or inert gas anneal at temperatures below about 850° C., such as temperatures between about 550° C. and about 850° C. Without being bound by a particular theory, the lower permissible thermal treatment temperature may be due at least partially to the reaction of diatomic hydrogen and oxygen to form water, such that process conditions that allow water to form may be used to heal the seams in the deposited oxide film. In some embodiments, water may be used rather than hydrogen and oxygen for the thermal treatment process.

In some embodiments the anneal may be performed using hydrogen-containing compounds without oxygen-containing compounds, or vice versa. In such embodiments, the hydrogen- or oxygen-containing compounds may react with hydrogen and/or oxygen within the deposited film to drive covalent bonding of between silicon and oxygen, as noted above. In some embodiments, the hydrogen-containing or oxygen-containing compounds may form water, which may help drive covalent bonding and reduce seams. Embodiments that include an anneal without hydrogen-containing species or without oxygen-containing species may be performed under the same or similar process conditions as embodiments using both. In some embodiments, annealing may be performed using oxygen radicals. Oxygen radicals may be generated by a remote plasma and delivered to the process chamber as described above in regard to FIG. 3.

In some embodiments the anneal treatment described herein may be performed with other metal oxide films in addition to silicon oxide films. For example, an anneal in the presence of hydrogen-containing and/or oxygen-containing compounds as described herein may be used to reduce seams and improve Me—O bonds in various metal oxide films. Metal oxide films that may be treated with an anneal to reduce seams include: Ta, Hf, Zr, Ge, W, Mo, Co, Ni, Y, Sn, Ti, or Al oxide films.

In some embodiments the anneal is done ex-situ of the process chamber that performs the oxide deposition. In other embodiments the anneal is performed in the same chamber that performs the oxide deposition. Ratios of hydrogen and oxygen for the thermal treatment may be between about 1:1 and about 10:1 H₂:O₂, such as about 5 slm: 5 slm, Process chamber pressure may be between about 15 torr and atmospheric pressure. Anneal temperatures may be at least about 500° C., about 600° C., about 700° C., or about 800° C. A time duration for thermal treatment is about 90 minutes, or between about 30 and about 180 min.

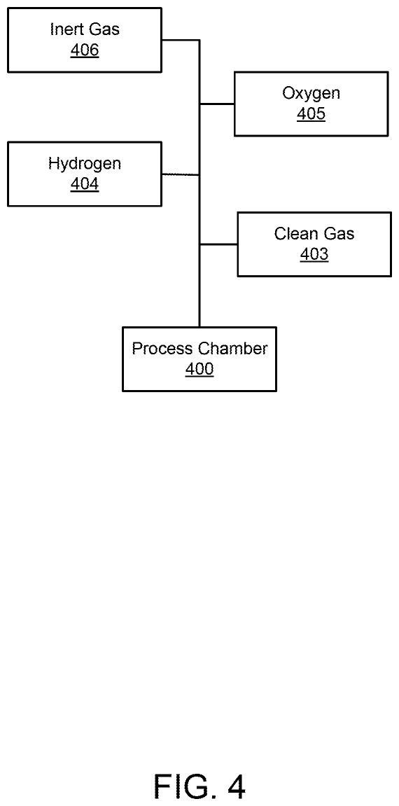

In some embodiments, a particular manifold is used to inhibit back-deflagration. This allows for higher amounts of hydrogen to be used while reducing the risk of violent explosions. FIG. 4 provides a block diagram of a manifold that may be used for deposition and/or thermal treatment processes as described herein. Manifolds 403 and 404 are positioned below manifolds 406 and 405, which flow inert gas and oxygen, respectively. The inert gas is used to control and inhibit the reaction of hydrogen and oxygen within the manifold. In some embodiments, the inert gas also facilitates the mixing of oxygen and hydrogen from manifolds 404 and 405, respectively. In some embodiments, the inert gas ensures that residual gas from any of manifolds 403, 404, and 405 does not remain within the manifold, which could lead to undesirable deposition within the manifold. Clean gas 403 may be NF₃ or F₂. Each of manifolds 403-406 lead to the process chamber, where processes as described herein are performed.

### Apparatus

The methods described herein may be performed by any suitable apparatus or combination of apparatus. A suitable apparatus includes hardware for accomplishing the process operations and a system controller having instructions for controlling process operations in accordance with the present disclosure. For example, in some implementations, the hardware may include one or more process stations included in a process tool. In the present disclosure, the thermal ALD/CVD and PEALD/PECVD may be performed in a single station/chamber.

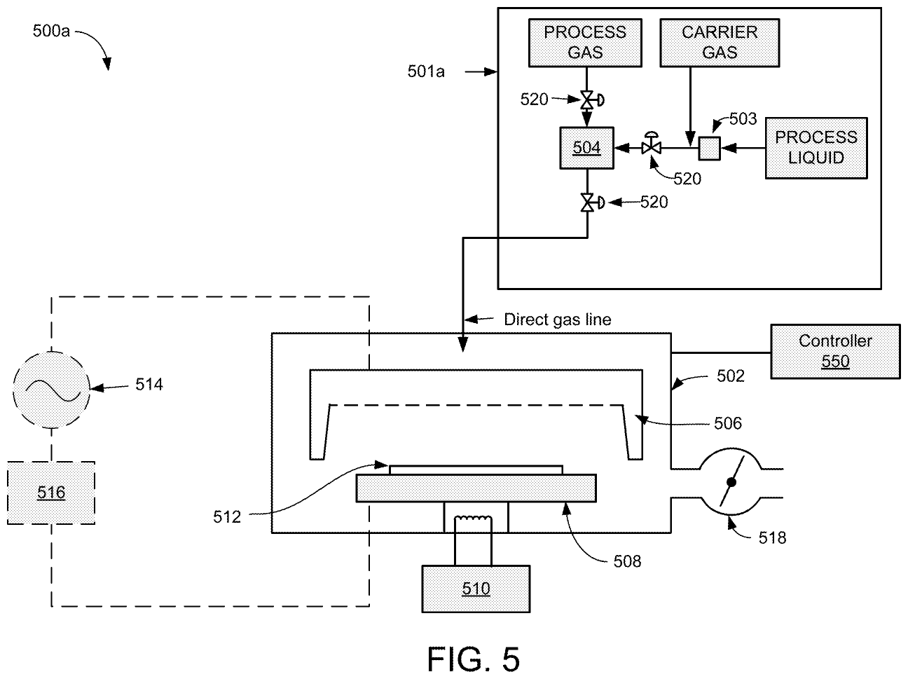

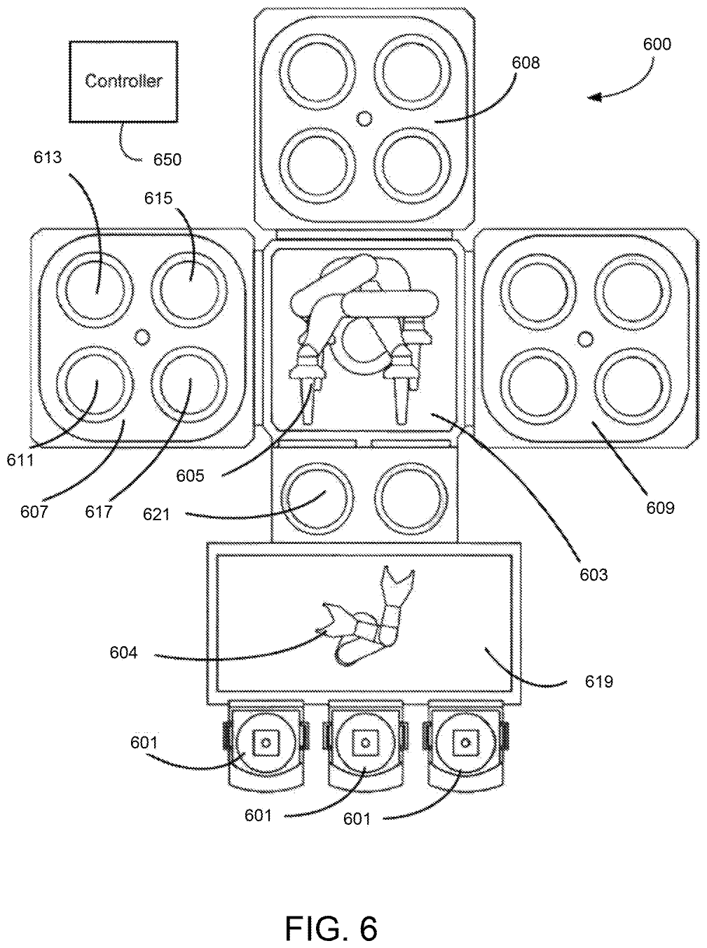

FIG. 5 is a schematic diagram of an example plasma processing apparatus for depositing a silicon-containing film using thermal AM according to some implementations. The plasma apparatus or process station 500a includes a plasma processing chamber 502 for maintaining a low-pressure environment. A plurality of plasma apparatuses or process stations 500a may be included in a common low-pressure process tool environment. For example, FIG. 6 depicts an implementation of a multi-station processing tool 600. In some implementations, one or more hardware parameters of the plasma apparatus or process station 500a including those discussed in detail below may be adjusted programmatically by one or more system controllers 550, The plasma apparatus or process station 500a can be configured to perform thermal ALD and PEALD, thermal CVD and PEALD, thermal ALD and PECVD, or thermal CVD and PECVD. in some implementations, the plasma apparatus or process station 500a can be configured to perform one or more PEALD cycles and one or more thermal ALD cycles to deposit a silicon oxide film on a substrate 56.

The apparatus or process station 500a fluidly communicates with reactant delivery system 501a for delivering process gases to a distribution showerhead 506. Reactant delivery system 501a includes a mixing vessel 504 for blending and/or conditioning process gases, such as a silicon-containing precursor in the vapor phase, for delivery to showerhead 506. In some implementations, the reactant delivery system 501a includes a mixing vessel 504 for blending and/or conditioning an oxygen-containing reactant (e.g., oxygen) for delivery to the showerhead 506. In some implementations, the reactant delivery system 501a includes a mixing vessel 504 for blending and/or conditioning hydrogen and an oxygen-containing reactant (e.g., oxygen) for delivery to the showerhead 506. One or more mixing vessel inlet valves 520 may control introduction of process gases to mixing vessel 504. Plasma of the oxygen-containing reactant may also be delivered to the showerhead 506 or may be generated in the plasma apparatus or process station 500a. The showerhead 506 may be fluidly coupled to the plasma processing chamber 502 for delivery of silicon-containing precursors and reactants into the plasma processing chamber 502,

As an example, the implementation of FIG. 5 includes a vaporization point 503 for vaporizing liquid reactant to be supplied to the mixing vessel 504. In some implementations, vaporization point 503 may be a heated vaporizer. In some implementations, delivery piping downstream of vaporization point 503 may be heat traced. In some examples, the mixing vessel 504 may also be heat traced. In one non-limiting example, piping downstream of vaporization point 503 has an increasing temperature profile extending from approximately 100° C. to approximately 150° C. at the mixing vessel 504. In some implementations, liquid precursor or liquid reactant may be vaporized at a liquid injector. For example, a liquid injector may inject pulses of a liquid reactant into a carrier gas stream upstream of the mixing vessel 504. In one implementation, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 503. In one scenario, a liquid injector may be mounted directly to mixing vessel 504. In another scenario, a liquid injector may be mounted directly to showerhead 506.

In some implementations, a liquid flow controller (LFC) upstream of vaporization point 503 may be provided for controlling a mass flow of liquid for vaporization and delivery to the plasma apparatus or process station 500a. For example, the ITC may include a thermal mass flow meter (MEM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some implementations, the LFC may be dynamically switched between a feedback control mode and a direct control mode. in some implementations, this may be performed by disabling a sense tube of the LFC and the PID controller.

The showerhead 506 distributes process gases toward a substrate 56. In the implementation shown in FIG. 5, the substrate 56 is located beneath the showerhead 506 and is shown resting on a substrate support 508, where the substrate support 508 is configured to support the substrate 56. The substrate support 508 may include a chuck, a fork, or lift pins (not shown) to hold and transfer the substrate 56 during and between the deposition operations. The chuck may be an electrostatic chuck, a mechanical chuck, or various other types of chuck as are available for use in the industry and/or for research. The showerhead 506 may have any suitable shape, and may have any suitable number and arrangement of ports for distributing process gases to the substrate 56.

In some implementations, the substrate support 508 may be raised or lowered to expose the substrate 56 to a volume between the substrate 56 and the show head 506. It will be appreciated that, in some implementations, substrate support height may be adjusted programmatically by a suitable system controller 550.

In another scenario, adjusting a height of the substrate support 508 may allow a plasma density to be varied during plasma activation cycles included in the process. At the conclusion of a processing phase, the substrate support 508 may be lowered during another substrate transfer phase to allow removal of the substrate 56 from the substrate support 508.

In some implementations, the substrate support 508 may be configured to be heated to an elevated temperature via a heater 510. In some implementations, the substrate support 508 may be heated to a temperature less than about 850° C., such as about between about 500° C. and about 750° C. or between about 500° C. and about 650° C., during deposition of silicon oxide films as described in the disclosed implementations. Further, in some implementations, pressure control for the apparatus or process station 700a may be provided by a butterfly valve 518. As shown in the implementation of FIG. 5, the butterfly valve 518 throttles a vacuum provided by a downstream vacuum pump (not shown), However, in some implementations, pressure control of the plasma processing chamber 502 may also be adjusted by varying a flow rate of one or more gases introduced to the plasma processing chamber 502. In some implementations, the pressure in the plasma processing chamber 502 may be controlled to be equal to or greater than about 7 Torr, equal to or greater than about 3 Ton, or between about 3 Torr and 10 Torr during deposition of silicon oxide films as described in the disclosed implementations.

In some implementations, a position of the showerhead 506 may be adjusted relative to the substrate support 508 to vary a volume between the substrate 56 and the showerhead 506. Further, it will be appreciated that a vertical position of substrate support 508 and/or showerhead 506 may be varied by any suitable mechanism within the scope of the present disclosure. In some implementations, the substrate support 508 may include a rotational axis for rotating an orientation of the substrate 56. It will be appreciated that, in some implementations, one or more of these example adjustments may be performed programmatically by one or more suitable system controllers 550,

In some implementations where plasma may be used as discussed above, showerhead 506 and substrate support 508 electrically communicate with a radio frequency (RF) power supply 514 and matching network 516 for powering a plasma in the plasma processing chamber 502. In some implementations, the plasma energy may be controlled by controlling one or more of a process station pressure, a gas concentration, an RF source power, an RF source frequency, and a plasma power pulse timing. For example, RF power supply 514 and matching network 516 may be operated at any suitable power to form a plasma having a desired composition of radical species. In some implementations, the RF power supply 514 and matching network 516 may be operated to apply plasma power to the plasma processing chamber 502 to ignite plasma generated from hydrogen and oxygen-containing reactants in the plasma processing chamber 502. Example plasma powers applied by the RF power supply 514 may be at least about 500 W, equal to or less than about 6 kW, or between about 500 W and about 6 kW. Likewise, RF power supply 514 may provide RF power of any suitable frequency. In some implementations, RF power supply 514 may be configured to control high- and low-frequency RF power sources independently of one another. Example low-frequency RF frequencies may include, but are not limited to, frequencies between 0 kHz and 500 kHz. Example high-frequency RF frequencies may include, but are not limited to, frequencies between 1.8 MHz and 2.45 GHz, or at least about 13.56 MHz, or at least about 27 MHz, or at least about 40 MHz, or at least about 60 MHz. It will be appreciated that any suitable parameters may be modulated discretely or continuously to provide plasma energy for the surface reactions. In some embodiments, other electrode configurations may be used to provide power to showerhead 506.

In some implementations, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some implementations, one or more plasma parameters may be programmatically adjusted based on measurements from such in situ plasma monitors. For example, an OES sensor may be used in a feedback loop for providing programmatic control of plasma power. It will be appreciated that, in some implementations, other monitors may be used to monitor the plasma and other process characteristics. Such monitors may include, but are not limited to, infrared (IR) monitors, acoustic monitors, and pressure transducers.

In some implementations, instructions for a controller 550 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some implementations, instructions for setting one or more reactor parameters may be included in a recipe phase. For example, a first recipe phase may include instructions for setting a flow rate of an inert and/or a precursor gas (e.g., the silicon-containing precursor), instructions for setting a flow rate of a carrier gas (such as argon), and time delay instructions for the first recipe phase. A second, subsequent recipe phase may include instructions for modulating or stopping a flow rate of an inert and/or a precursor gas, and instructions for modulating a flow rate of a carrier or purge gas and time delay instructions for the second recipe phase. A third recipe phase may include instructions for modulating a flow rate of an oxygen-containing reactant gas such as oxygen, instructions for modulating a flow rate of hydrogen gas, instructions for modulating the flow rate of a carrier or purge gas, and time delay instructions for the third recipe phase. A fourth, subsequent recipe phase may include instructions for modulating or stopping a flow rate of an inert and/or a reactant gas, and instructions for modulating a flow rate of a carrier or purge gas and time delay instructions for the fourth recipe phase. The fourth recipe, in some implementations, may include instructions for igniting plasma of the oxygen-containing reactant. it will be appreciated that these recipe phases may be further subdivided and/or iterated in any suitable way within the scope of the disclosed implementations.

In certain implementations, the controller 550 has instructions to perform the operations described in the present disclosure. For example, the controller 550 may be configured with instructions to perform the following operations: expose a substrate 56 to a silicon-containing precursor to adsorb onto a surface of the substrate 56 in the plasma processing chamber 502, flow hydrogen and oxygen-containing reactant towards the substrate 56 in the plasma processing chamber 502, and heat the substrate 56 to an elevated temperature, where the hydrogen and oxygen-containing reactant react with one another in the plasma processing chamber 502, where a layer of silicon oxide film is formed on the substrate 56. In some implementations, the elevated temperature is between about 500° C. and about 650° C. and the oxygen-containing reactant is oxygen. In some implementations, the controller 550 is further configured with instructions to perform the following operation: deposit one or more additional layers of the silicon oxide film on the substrate 56 via PEALD in the plasma processing chamber 502. In some implementations, the controller 550 configured with instructions for flowing the hydrogen and oxygen-containing reactant is configured with instructions for performing the following operations: flow the oxygen-containing reactant continuously into the plasma processing chamber 502, and pulse hydrogen at regular intervals into the plasma processing chamber 502. In some implementations, the controller 550 may include any of the features described below with respect to system controller 650 of FIG. 6.

FIG. 6 is a schematic diagram of an example process tool for performing the disclosed implementations. A multi-station processing tool 600 may include a transfer module 603. The transfer module 603 provides a clean, pressurized environment to minimize the risk of contamination of substrates being processed as they are moved between various reactor modules. Mounted on the transfer module 603 are multi-station reactors 607, 608, and 609, referred to in this context as processing chambers or reactors or tool modules or modules. Each reactor is capable of performing deposition processes such as PEALD, thermal ALD, PECVD, or thermal CVD. One or more of the reactors 607, 608, and 609 may be capable of performing soaking/cleaning, plasma treatment, etching, annealing, or other operations. The reactors 607, 608, and 609 may include multiple stations 65, 613, 615, and 617 that may sequentially or non-sequentially perform operations in accordance with the disclosed implementations. While a depicted reactor 607, 608, or 609 is depicted with four stations, it will be understood that a reactor according to the present disclosure may have any suitable number of stations. For example, in some implementations, a reactor may have five or more stations, while in other implementations, a reactor may have three or fewer stations. Each station may be configured for deposition by PEALD, thermal AID, PECVD, or thermal CVD, or configured for different phases of a deposition process. Each station may include a substrate support configured to be heated to an elevated temperature as well as a showerhead or gas inlets for delivering gases.

The multi-station processing tool 600 also includes one or more substrate source modules 601 where substrates are stored before and after processing. An atmospheric robot 604 in the atmospheric transfer chamber 619 first removes substrates from the one or more substrate source modules 601 to load locks 621. While the implementation depicted includes load locks 621, it will be appreciated that, in some implementations, direct entry of a substrate into a process station may be provided. A substrate transfer device 605, such as a robot arm unit, in the transfer module 603 moves the substrates from the load locks 621 to and among the reactors 607, 608, and 609. This can be done in a pressurized (e.g., vacuum) environment. The multi-station processing tool 600 may perform one or more of the processes described in the present disclosure as well as other operations such as soaking/cleaning, plasma treatment, annealing, etc. Such processes may be performed in the multi-station processing tool 600 without introducing a vacuum break

FIG. 6 may also include a system controller 650 employed to control process conditions and hardware states of multi-station processing tool 600. System controller 650 may include one or more memory devices, one or more mass storage devices, and one or more processors. Processor may include a CPU or computer, analog and/or digital input/output connections, stepper motor controller boards, etc.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc. These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some implementations, be part of a recipe defined by process engineers to accomplish one or more processing operations during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing operations to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing operations to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process operation or operations to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Returning to the implementation of FIG. 6, in some implementations, system controller 650 controls all of the activities of multi-station processing tool 600. System controller 650 executes system control software stored in mass storage device, loaded into memory device, and executed on processor. Alternatively, the control logic may be hard coded in the controller 650. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 658 may include instructions for controlling the timing, mixture of gases, chamber and/or station pressure, chamber and/or station temperature, water temperature, target power levels, RF power levels, RF exposure time, substrate pedestal, chuck and/or susceptor position, and other parameters of a particular process performed by multi-station processing tool 600. System control software may be configured in any suitable way. :For example, various process tool component subroutines or control objects may be written to control operation of the process tool components necessary to carry out various process tool processes. System control software may be coded in any suitable computer readable programming language.

in sonic implementations, system control software may include input/output control (IOC) sequencing instructions for controlling the various parameters described above. For example, each phase of a thermal ALD cycle or each phase of a PEALD cycle may include one or more instructions for execution by system controller 650. The instructions for setting process conditions for an ALD process phase may be included in a corresponding ALD recipe phase. In some implementations, the ALD recipe phases may be sequentially arranged, so that all instructions for an ALD process phase are executed concurrently with that process phase.

Other computer software and/or programs stored on mass storage device and/or memory device associated with system controller 650 may be employed in some implementations. Examples of programs or sections of programs for this purpose include a substrate positioning program, a process gas control program, a pressure control program, a heater control program, and a plasma control program.

A substrate positioning program may include program code for process tool components that are used to load the substrate onto pedestal and to control the spacing between the substrate and other parts of multi-station processing tool 600.

A process gas control program may include code for controlling gas composition and flow rates and optionally for flowing gas into one or more process stations prior to deposition in order to stabilize the pressure in the process station. In some implementations, the controller includes instructions for depositing a first silicon oxide layer by thermal ALD in a plasma processing chamber, and depositing a second silicon oxide layer by PEALD in the same plasma processing chamber. In some implementations, the controller includes instructions for depositing a layer of silicon oxide by delivering silicon-containing precursor to a substrate in a dose phase and co-flowing hydrogen and oxygen towards the substrate in a thermal oxidation phase.

A pressure control program may include code for controlling the pressure in the process station by regulating, for example, a throttle valve in the exhaust system of the process station, a gas flow into the process station, etc. In some implementations, the controller includes instructions for providing a chamber pressure in the plasma processing chamber to be at least about 3 Torr prior to performing thermal ALD of silicon oxide layer.

A heater control program may include code for controlling the current to a heating unit that is used to heat the substrate. Alternatively, the heater control program may control delivery of a heat transfer gas (such as helium) to the substrate. In certain implementations, the controller includes instructions for heating the substrate to an elevated temperature during a thermal oxidation phase of a thermal ALD cycle, where the elevated temperature is between about 400° C. and about 650° C.

A plasma control program may include code for setting RF power levels and exposure times in one or more process stations in accordance with the implementations herein. In some implementations, the controller includes instructions for igniting plasma at an RF power level between about 10 W and about 200 W during a thermal oxidation phase of a thermal ALD cycle when hydrogen and oxygen are being co-flowed.

In some implementations, there may be a user interface associated with system controller 650. The user interface may include a display screen, graphical software displays of the apparatus and/or process conditions, and user input devices such as pointing devices, keyboards, touch screens, microphones, etc.

In some implementations, parameters adjusted by system controller 650 may relate to process conditions. Non-limiting examples include process gas composition and flow rates, temperature, pressure, plasma conditions (such as RF power levels and exposure times), etc. These parameters may be provided to the user in the form of a recipe, which may be entered utilizing the user interface.

Signals for monitoring the process may be provided by analog and/or digital input connections of system controller 650 from various process tool sensors. The signals for controlling the process may be output on the analog and digital output connections of multi-station processing tool 600. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 650 may provide program instructions for implementing the above-described deposition processes. The program instructions may control a variety of process parameters, such as DC power level, RF bias power level, pressure, temperature, gas flow composition, flow rates, etc. The instructions may control the parameters to operate thermal ALD or thermal CVD of silicon oxide film according to various implementations described herein.

The system controller 650 will typically include one or more memory devices and one or more processors configured to execute the instructions so that the apparatus will perform a method in accordance with the disclosed implementations. Machine-readable, non-transitory media containing instructions for controlling process operations in accordance with the disclosed implementations may be coupled to the system controller.

The various hardware and method implementations described above may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility.

### Conclusion

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments, Accordingly, the present embodiments are to be considered as illustrative and not restrictive, and the embodiments are not to be limited to the details given herein,

1. A method, comprising:
depositing an oxide gapfill material into patterned features of a layer of a substrate using a hydrogen-containing oxidizing chemistry, wherein the deposited oxide gapfill material has a plurality of seams within the patterned features; and
thermally treating the deposited oxide gapfill material in the presence of hydrogen-containing compounds and/or oxygen-containing compounds to thereby reduce the extent of the seams.

2. The method of claim 1, wherein depositing the oxide gapfill material is performed by an atomic layer deposition (ALD) process.

3. The method of claim 2, wherein the ALD process comprises one or more cycles of:
flowing oxide gapfill precursor, and
flowing an oxidizing chemistry comprising H₂ and O₂.

4. The method of claim 3, wherein the oxidizing chemistry additionally comprises N₂O, CO₂, H₂O, or combinations thereof.

5. The method of claim 3, wherein a ratio of volumetric flow rate between H₂ and O₂ when flowing the oxidizing chemistry is between about 1:10 and about 1:1.

6. The method of claim 3, wherein the oxide gapfill precursor includes aminosilanes, halosilanes, alkylsilanes, silane, or combinations thereof.

7. The method of claim 1, wherein depositing the oxide gapfill material is performed by a chemical vapor deposition process.

8. The method of claim 1, wherein the oxide gapfill material is silicon oxide.

9. The method of claim 1, wherein an aspect ratio of the patterned features is between about 5:1 and about 80:1.

10. The method of claim 1, wherein thermally treating the deposited oxide gapfill material is performed at a temperature of at least about 400° C.

11. The method of claim 1, wherein thermally treating the deposited oxide gapfill material is performed at a temperature between about 400° C. and about 850° C.

12. The method of claim 1, wherein thermally treating the deposited oxide gapfill material is performed under conditions that form H₂O.

13. The method of claim 1, wherein thermally treating the deposited oxide gapfill material is performed in the presence of H₂ and O₂.

14. The method of claim 13, wherein a volumetric ratio of H₂ to O₂ during thermally treating the deposited oxide gapfill material is between about 10:1 and about 1:1.

15. The method of claim 1, wherein the oxygen-containing compounds include N₂O, CO₂, H₂O, or combinations thereof.

16. The method of claim 1, wherein the hydrogen-containing compounds include protic acids.

17. The method of claim 1, wherein a hydrogen % within the deposited oxide gapfill material prior to thermally treating the deposited oxide gapfill material is at least about 0.1%.

18. The method of claim 1, wherein the layer includes polySi-SiO₂, W—SiO₂, SiN—SiO₂, SiNO—SiO₂, SiCO—SiO₂, SiC—SiO₂, Ta—SiO₂, Ta, Hf, Zr, Ge, GeO₂, Al₂O₃, TiO₂, NiO, CoO, Co₂O, MoO₃, HfO, TaO or combinations thereof.

19. A method, comprising:
receiving a substrate having patterned features within a first layer;
depositing a oxide gapfill material into the patterned features; and
thermally treating the deposited oxide gapfill material in the presence of hydrogen-containing compounds and/or oxygen-containing compounds.

20. A method, comprising:
prior to thermally treating a substrate, depositing an oxide gapfill material into patterned features of the substrate by an atomic layer deposition (ALD) process, wherein the ALD process comprises one or more cycles of:
flowing gapfill precursor, and
flowing an oxidizing chemistry comprising H₂ and O₂.

21. (canceled)

22. (canceled)
